(19) United States
(12) Patent Application Publication
(10) Pub. No.: US 2005/0258863 A1
(43) Pub. Date: Nov. 24, 2005

(54) Quaternary and trinary logic switching circuits

(76) Inventors: Augustine W. Chang, San Jose, CA (US); I-pieng Peter Kao, Sunnyvale, CA (US)

Correspondence Address: SAWYER LAW GROUP LLP, P.O. Box 51418, Palo Alto, CA, 94303, US

(21) Appl. No.: 10/850,525

(22) Filed: May 20, 2004

(51) Int. Cl. H03K 19/02

(52) U.S. Cl. 326/59

(57) ABSTRACT

A logic circuit comprising a quaternary logic switching circuit which includes a multilevel storage cell (MLSC), and the trinary or variable threshold logic means to yield an improved space, power, and time-efficient performance device is disclosed. The present invention is used for the implementation of a customized new logic design to further improve the cost-effectiveness of the application. Advanced circuit solutions are provided using asynchronous clock controlled functional units which are field programmable. A diode capacitor ladder chain is also used on an on-chip power supply multiplier to support internal high voltage operations. A digital-to-analog-to-digital translation (DADT) apparatus is also provided utilizing the above identified circuits. Finally, a printed circuit board (PCB) net driver with a trinary signal wire provides 50% bandwidth increase over conventional binary solutions.

### RELATED APPLICATIONS

The present invention is related to copending U.S. patent application entitled “3D Flash EEPROM Cell and the Methods of Implementing the Same”, Ser. No. 10/800,257, filed on Mar. 11, 2004, and assigned to the assignee of the present invention; and copending U.S. patent application entitled “Variable Threshold Transistor for the Schottky FPGA and Multilevel Storage Cell Flash Arrays”, Ser. No. 10/817,201, filed on Apr. 2, 2004, and assigned to the assignee of the present invention which is related to copending U.S. patent application entitled “SCL Type FPGA with Multi-Threshold Transistors and Method for Forming Same”, Ser. No. ______ (3070P) filed on Apr. 19, 2004, and assigned to the assignee of the present invention, and U.S. patent application entitled “Distributive Computing Subsystem of Generic IC Parts”, Ser. No. ______, (3072P) filed on May 7, 2004, and assigned to the assignee of the present invention, all of which are incorporated by reference herein.

### FIELD OF THE INVENTION

The present invention relates generally to integrated circuits and more particularly to low power implementation of high speed, high density, and high capacity logic switching circuits.

### BACKGROUND OF THE INVENTION

The electrical erasable and programmable EEPROM memory devices have become more widely used in the last decade. The technological advances and broad product applications have made EEPROM memory devices the most viable candidate for implementing SOC level component integrations.

On the process and device technology side, the general practice of memories has been focused on the miniaturization of the physical size of the storage bit, scaling down the cell operating voltages and currents and therefore lowering power consumption. Thereby implementing multilevel signal storages per physical cell area can be implemented. In addition, chip apparatus can be built to manage per bit, byte, large and partial arrays, resource sharing schemes. The ultimate goal is to achieve highest level of system integration with mixed analog and logic circuits in a common chip and therefore improve IC devices with performance, reliability, system efficiency and capacity etc.

Flash memory is a good choice for information storage devices based upon their increasing capacity. The name of “Flash memory and logic device” is adopted based upon the device's fast operation and its use in large arrays. The Flash devices are closely related to the Flash technology. The density, power, and speed capability of Flash arrays exceed what is offered by rotating disks, so the semiconductor EEPROM is replacing the mechanical disk medium in many applications. The Flash memory can also replace DRAM/SRAM for certain applications if the speed/performance requirements are met. Flash memory is nonvolatile and has high density per cell for information storage.

The EEPROM device may be applicable as ideal memory device; both as standalone memory/logic part and as part of an embedded storage/logic unit in an ASIC. The Flash device has several attractive features such as compactness, low power and high speed. A Flash device could replace conventional mechanical and optical disks, controller and microprocessors for network and communications. There is an interest to extend the use of the Flash devices in printed circuit board (PCB) assemblies. However, conventional PCB subsystem assemblies still use standalone logic chips, memory chips, and discrete components interconnecting them with the PCB wiring. It is desirable for a small system such as SD card, stick card, pen drives, PDA, mobile phone to merge the memory capacity, processing power, and even some analog functions in a universal IC. This will be advantageous in both the space and cost savings, and to optimize performance.

There are numerous prior art methods and systems in Flash technology, which has been utilized for information storage. The Flash transistor has been successfully developed as either a single bit or a dual bit system storage circuit element. However, typically the Flash transistor is not utilized as logic circuit element.

Field Programmable Logic Devices represented by PLA solutions utilizing Flash devices are well known. The field programmable ICs either reconfigure prime term logic arrays or functional units with on-chip wiring switches and tracks. However, these devices are not utilized to make functional units by directly programming the threshold of the switch transistor and in configuring a basic logic circuit unit. A typical FPGA contains standalone CMOS-TTL implementations with device capacity in the range of a couple hundred gates to about 10 k gates. The basic building blocks contain I/O and logic elements for the latch and the TTL hard and soft macros, RAM arrays, wiring switches and tracks. The most advanced FPGA uses 1.8V supply. The device is highly popular for it flexibility and supported software package. It is difficult to merge a Flash array with the CMOS-TTL logic circuit for the process and circuit compatibility issues, and there is no business advantage to merge these technologies for neither the manufacturers of FPGA nor the manufacturers of Memory standard parts.

In conventional integrated circuits billions of transistors are successfully found therein. However, many parts that perform different functions are still difficult to integrate. One of the most obvious reasons for this difficulty is the process compatibility issue. It is difficult to merge present technologies because of different process cost objectives for volume parts such as memory and logic units. Memory commodity parts are remarkably cost sensitive and even a minor complication would cost more to the standardized parts. As long as the standardized parts are selling in high volume, there is a barrier for any newly emerged parts or approaches to begin. Usually a tremendous breakthrough in speed, density, power, or capacity is required to make this change. In addition typically reliability-availability-serviceability (RAS) must be of a high quality for such a breakthrough.

Nevertheless, an opportunity to merge the FPGA and Flash technology is desired. By adding the computing power with the densest logic circuit to the densest storage devices, a universal part is emerged, and great design flexibility is added to device capacity and performance options. Furthermore, logic circuits may be augmented to contain analog function and multi-valued logic, and still perform at low power.

Computer systems today are based on two-valued (binary) logic. In most cases, a signal wire carries only two signal levels at any time. Boolean algebra and its associated developments have helped the acceptance and exploitation of binary logic. However, the most pressing problems in systems made from binary logic systems are interconnection issues, both of nets on chip and between chips. Accordingly, what is needed is a system and method for addressing the need for such devices with at least some or many signal wires carrying more than two signal levels. The present invention addresses such a need.

### SUMMARY OF THE INVENTION

A logic circuit comprising a trinary or quaternary logic switching circuit which includes a multilevel storage cell (MLSC), and the variable threshold logic (VTL) means to yield an improved space, power, and time-efficient performance device is disclosed. The present invention is used for the implementation of a customized new logic design to further improve the cost-effectiveness of the application.

### BRIEF DESCRIPTION OF THE DRAWINGS

FIG. 1 shows PCB schematic block diagrams of the PCB subsystem built from the standalone IC parts (prior arts), and the invented field programmable intelligent memory chips.

FIG. 2 shows the proposed MLC transistor cross-section, SCL circuit schematic and horizontal layout.

FIG. 3 shows all critical device cross sectional views of the present invention.

FIG. 4 shows prior arts of the conventional FPGA solutions using CMOS-TTL ICs.

FIG. 5 shows programming means of a switching transistor of the SCL type FPGA logic gate unit, the programming algorithm and logic state flow diagram.

FIG. 6 shows the SFPGA on-chip transmission line terminating scheme, MUX and comparator schemes.

FIG. 7 describes quaternary logic operator, hardware and software means.

FIG. 8 describes trinary logic circuit, a self biased tri-state buffer means.

FIG. 9 describes SFPGA chip implementation and resource allocation.

FIG. 10 describes the iterative rule to construct the Quaternary sorter.

FIG. 11 gives the functional specification of the comparison unit in quaternary logic.

FIG. 12 shows the truth table of 3 quaternary operators to be used for the sorter.

FIG. 13 gives a design of a quaternary latch for constructing sequential circuits.

FIG. 14 depicts the design of the comparison unit in quaternary logic.

FIG. 15 shows in Quaternary embodiment a bitonic sorter of 4 inputs and 4 outputs (size 4).

### DETAILED DESCRIPTION

The present invention relates generally to integrated circuits and more particularly to multileveled logic switching circuits. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

The present invention utilizes device and system architecture for providing intelligent nonvolatile subsystems. The nonvolatile subsystem encompasses embedded units of Flash and memory arrays (SRAM, DRAM, ROM) and programmable logic arrays. The goal is to optimize an organization of low cost, high capacity, distributive computing and memory storages. Flash transistors and SBD-CMOS transistors are the basic circuit elements to implement the various hardware constructs. SFPGA software and transmission line signal control means are key to ensure high performance operations.

SFPGA techniques are utilized to allocate and configure certain portion of the logic circuits of a memory intensive chip. Both circuit unit types can be mixed to form a universal programmable device with Logic and Storage arrays. The users can field program certain high performance critical nets, IO ports, buffers, and clocking constructs. A wide performance range switching operations can be supported. Prior arts of fine-tuning clocking systems, reflection containment, data transfer protocols, and collision detection and error correction issues from leading vendors are greatly improved by the present invention.

Prior art U.S. Pat. No. 6,590,800 entitled “Schottky diode static random access memory (DSRAM) device, a method for making same, and CFET based DTL”, issued Jul. 8, 2003, by the inventor of this application describes a process and circuit scheme to lower the logic and RAM cell supply voltage to 1.2V and lower the current down to sub microamperes. By lowering the current and voltage in this manner, the array peripheral organization can be revamped using low power logic circuits. Copending U.S. patent application entitled “3D Flash EEPROM Cell and Methods of Implementing the Same”, Ser. No. ______ (3064), copending U.S. patent application entitled “Variable Threshold Transistor for the Schottky FPGA and Multilevel Storage Cell Flash Arrays”, Ser. No. ______ (3065) copending U.S. patent application entitled “SCL Type FPGA with Multi-Threshold Transistors and Method for Forming Same”, Ser. No. ______ (3070P), and copending U.S. patent application entitled entitled “Distributive Computing Subsystem of Generic IC Parts”, Ser. No. ______ (3072P), also disclose these features and are incorporated by reference herein. These features therefore allow for the development of:
1. Standalone Flash memory circuits with low power peripheral logic.
2. Flash memory arrays as embedded ASIC units with other functional units on the same ship. One example of such a chip is the mix of a functional unit with low power SCL type gate arrays for a field reprogrammable logic gate array (SFPGA) device.

A system and method in accordance with the present invention utilizes memory arrays with certain field programmable logic resources to provide circuit functionality and inter unit connectivity in the PCB. Ratios for the right mixture of the fixed and re-configurable units are at the discretion of the user as each functional part is defined.

The combined chips provide intensive large (Gbit) storage capacity plus a large number (10-100 k) of gates, relatively smaller dedicated physical resources of processing and buffering power, re-configurable ports, and stored software constructs. Wide application chip sets can be formed from the embedded memory, processor and logic arrays in accordance with the present invention. Utilizing the system and method in accordance with the present invention, a plural number of chips can form subsystems with single to large string of super or universal (UIC) chips. Finally, subsystem PCBs can provide distributive computing powers by partitioning them with various PCB arrangements and instantiated controls through reconfiguration procedures utilizing a system and method in accordance with the present invention.

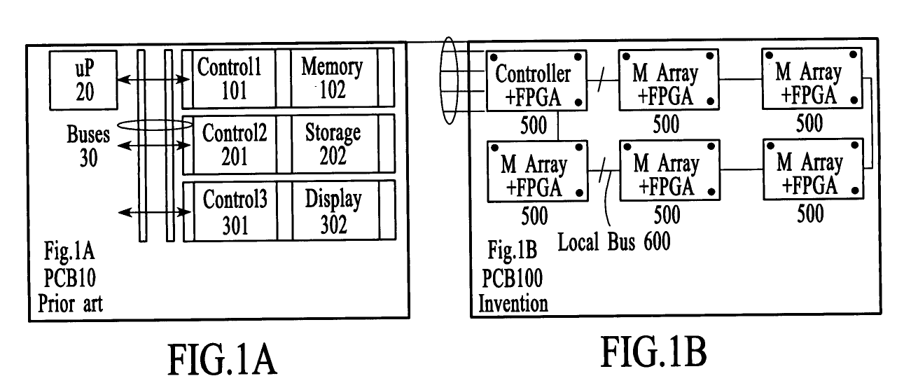

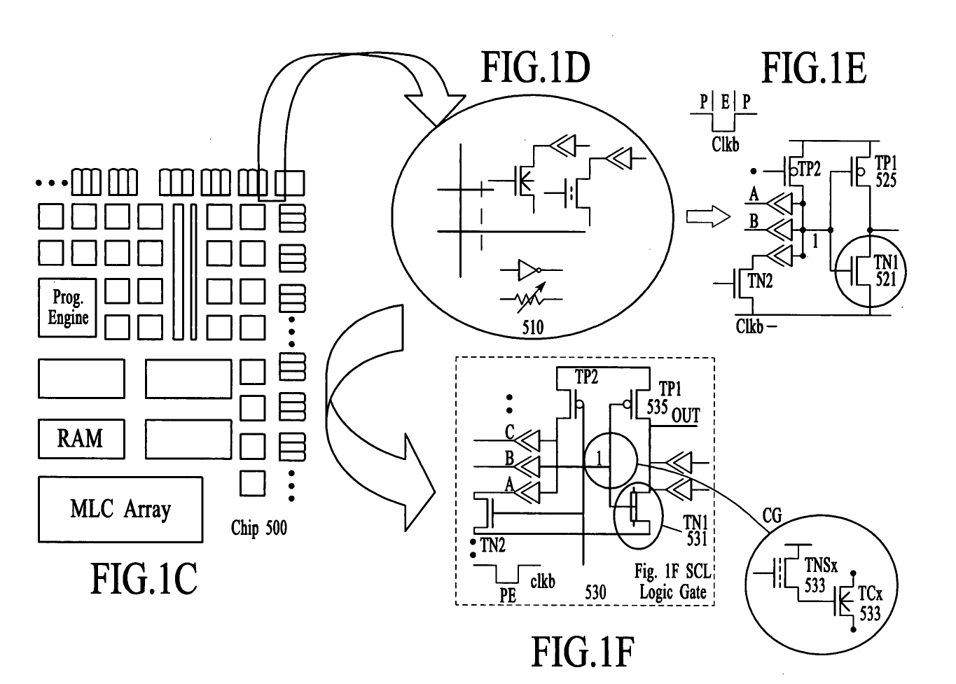

FIG. 1A shows a prior art of a host processor uP chip 20, memory module, or semiconductor disk PCB parts. Standalone IC parts are used. Usually the subsystems are formed by a ASIC controller chip(s) and several standalone commodity chip(s), signal buffers (address regenerators, CAS, RAS controls), crystal oscillators, terminators, power regulators etc, FPGA chips, and memory chips (DRAM or MLC chips).

FIG. 1B illustrates a plurality of printed circuit board subsystems in accordance with the present invention. Chipsets of major functions (i.e., IO or memory) are designed by semi-custom IC parts. The part utilizes SFPGA and storage arrays in accordance with the present invention. Each chipset houses certain portions of hardwired logic and storage arrays. Wiring resource and on-chip apparatus for reconfigurations are provided.

One preferred embodiment shown in FIG. 1B is the memory or storage subsystem. The memory subsystem comprises USB (or memory as multimedia cards) semiconductor drives. Each drive PCB 100 has USB interface port 400, controller or buffer chip 700, and local bus 600 with populated memory chips 500. The USB port provides a simple low speed (10 s of MHz) interfaces while the local bus can be high speed (100 s MHz) and high capacity. Both chip types contain pre-allocated real estate resources. Specific application oriented designs (USB, MMC, SD, FBDIMM, etc.) are supported by a UIC library, which are composed of hard and soft macro designs; IO functions, buffers, computing logics, large storage arrays and CAE simulating, placement, and routing software. The CAE software may include but is not limited to processing device parameters extraction, simulation modules, place and wiring programs, utilities, machine OS, reconfiguration procedures and test codes.

Flash Transistors for Embedded Memory and Logic Solutions

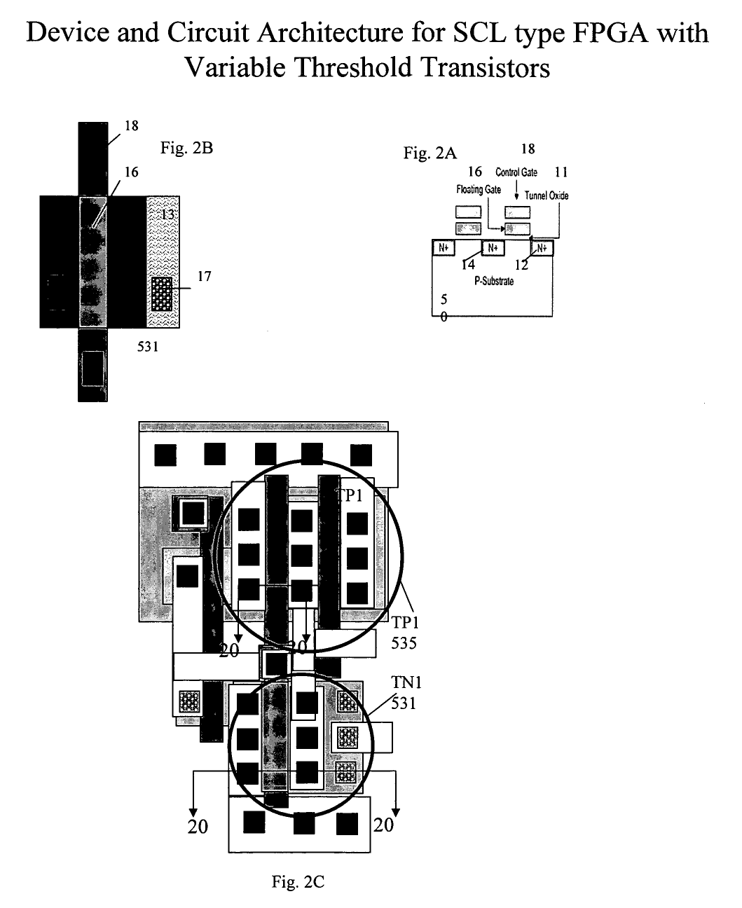

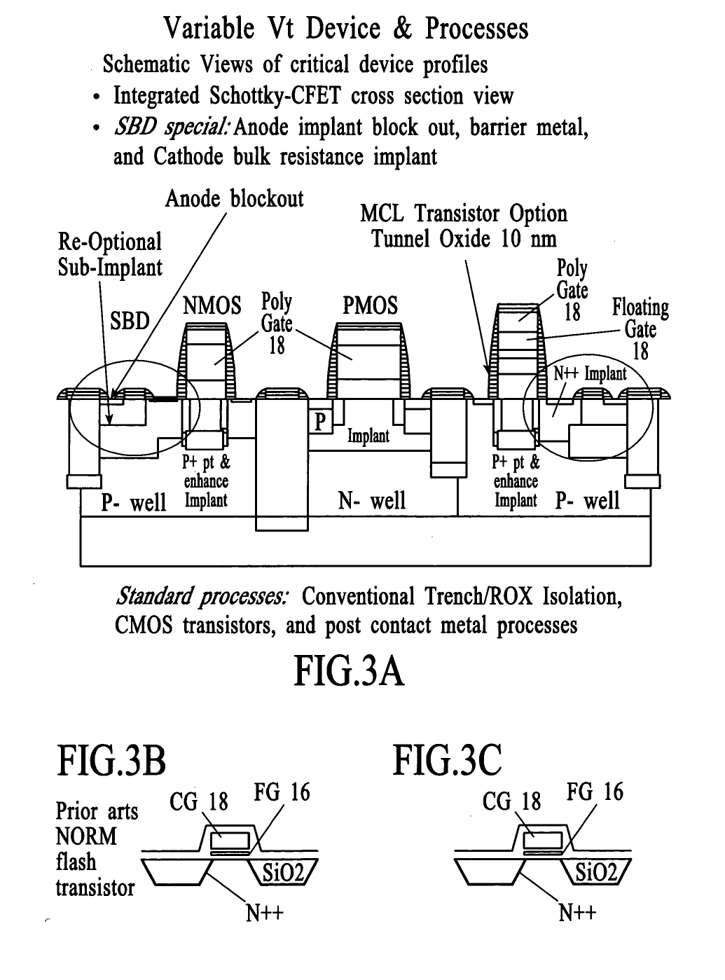

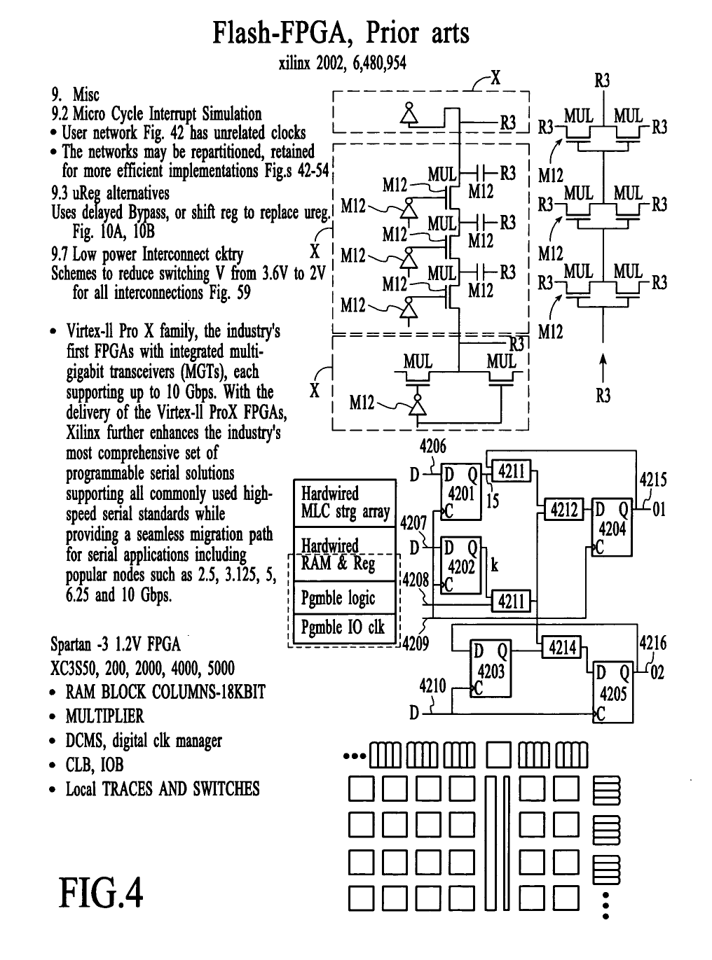

The process technology of the present invention devices emphasizes the compatibility for making Flash transistors, CMOS transistors, and Schottky barrier diodes. FIGS. 1E and 1F illustrate the two versions of SCL logic circuits implemented by the hardwired fixed Vt CMOS transistor and the variable Vt MLC switching transistors. FIG. 2 shows the circuit layout of the MLC storage cell and the logic circuit, and FIG. 3 shows all circuit element device cross sections.

One of ordinary skill readily recognizes that more variations can be derived from the teachings of this invention by mixing low power SCL circuits with Flash array and FPGA for other applications at system and device levels.

The cost of Flash memory has been significantly reduced in a per bit basis by the NAND Flash invention. The basic cell of a NAND Flash memory can be SLC or MLC. In the MLC case, the integration of computational logic to MVL functional blocks results in the current invention. Due to the capability of SFPGA and multiple valued logic (MVL) gates, the invention is extended to a useful Quaternary sorter implementation.

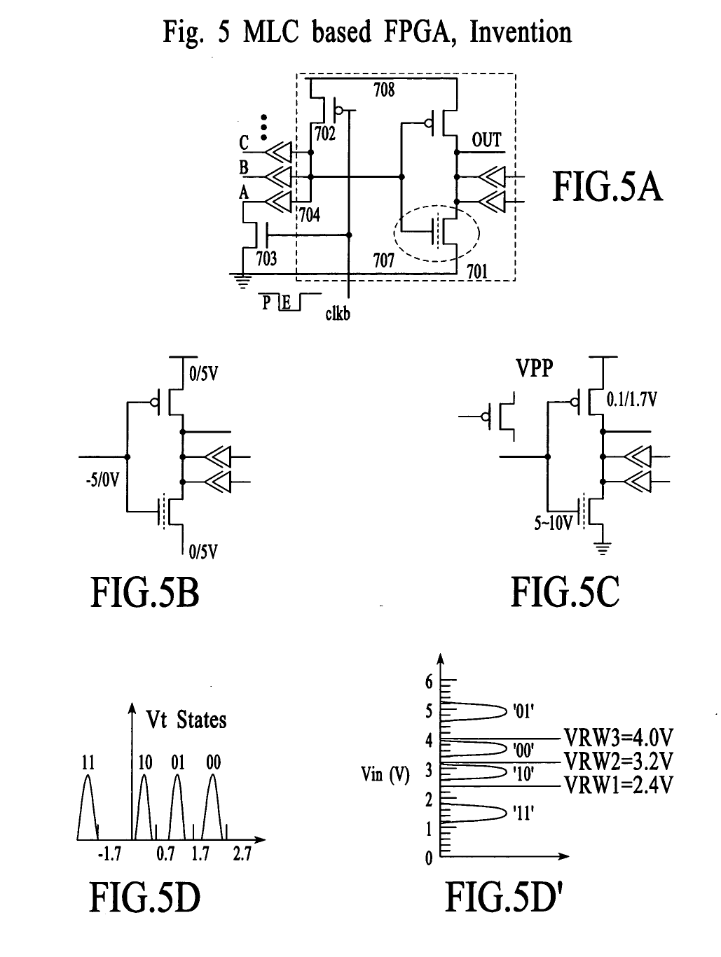

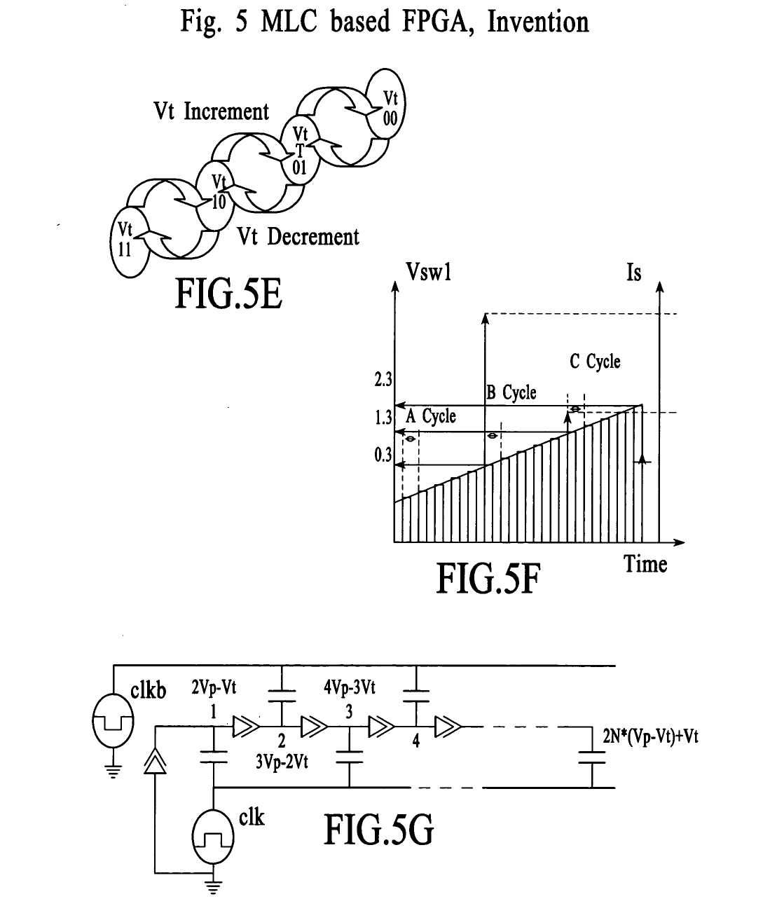

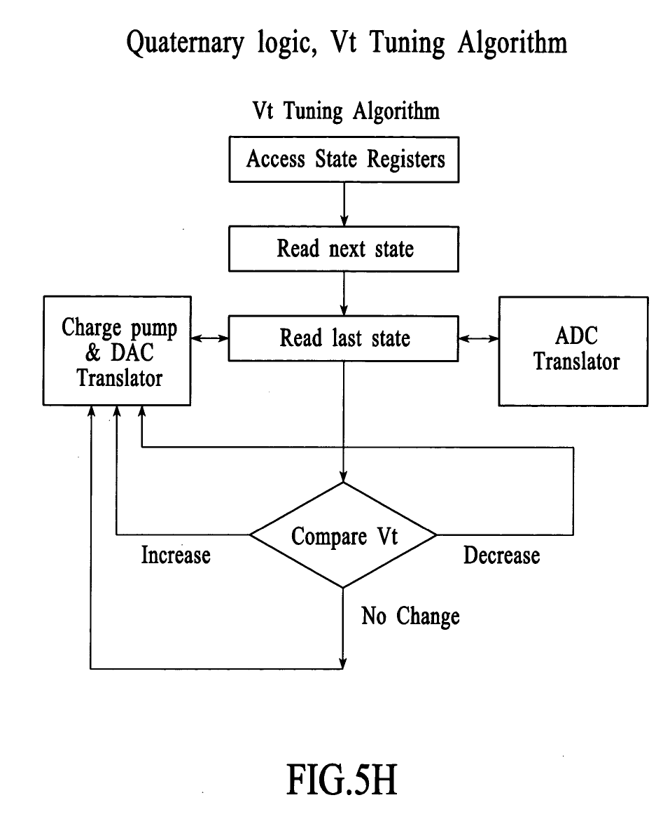

FIG. 5A shows a SCL 701 employing a MLC switching transistor 707 in its inverter part. FIGS. 5B and 1C show respectively the biasing conditions to program (Increase Vt) or Erase (Decrease Vt) to device 707 in circuit unit 701. During the initialization windows, the apply conditions are delivered by pulsed cycles to the target nodes by simple pass transistor(s), which are driven by RAM bits. Or they may be controlled by MLC switch directly by connected wiring tracks. FIG. 5D and 5D′ shows the designed charge distributions for the 4 programmed states for the 707 device(s). Table 1 below listed the applied node conditions during programming operations.

TABLE 1
Logic cell operation during POR or Re-configuration cycles

```
Programming conditions for the selected Cells.
    VG = 5˜10 V pulses
    Vout = 0.7 V (Vmode), or Iout = −100 uA (Imode)
    Verify VT = 0.7 V (Default), 1.7 V, 2.7 V
Erase conditions
    VG = 0/−5 V pulses
    Vout = 5/0 V
    Verify Vt = −1 V wrt source
Advantages
    Field programmable generic device
    Mixed NV Logic & Memory
    Bit-wise Vt adjustment against,
        Write/Read disturbance
        Aging and leveling
```

The state transit diagram and programming cycles are shown in FIGS. 5E and 5F. FIG. 5H shows the charge pump algorithm. The charge pump circuit is invented in FIG. 5H. While the even and odd nodes of the charge pump ladder are pushed by the complementary clock phases, the capacitors do see higher stresses, but the diode reverse stress remains constant at 1 VCC. This is particularly favoring the N-type SBD devices, which have zero diffusion capacitance, small pocket capacitance, but is sensitive to reverse biasing stresses. The diode and capacitor pairs can also build a negative power supply generator and charge pump chain. This was not shown, but certain device property and cautions must be observed.

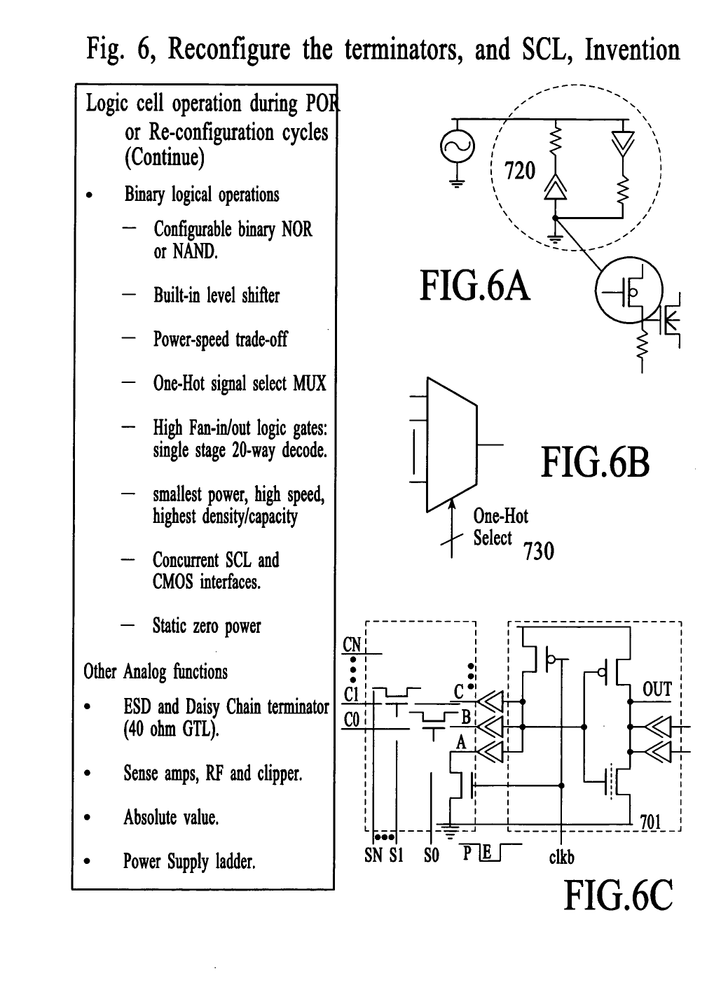

FIG. 6A shows the scheme to reconfigure an IO pad with Schottky clamp pairs. This will instantiate the port to an on-chip terminator, all the receivers in a long haul transmission line will yield clean waveforms without reflections. On the other hand, the port may be reconfigured as line driver when the terminator is open circuit.

The Quaternary Logic Gate and State Machines

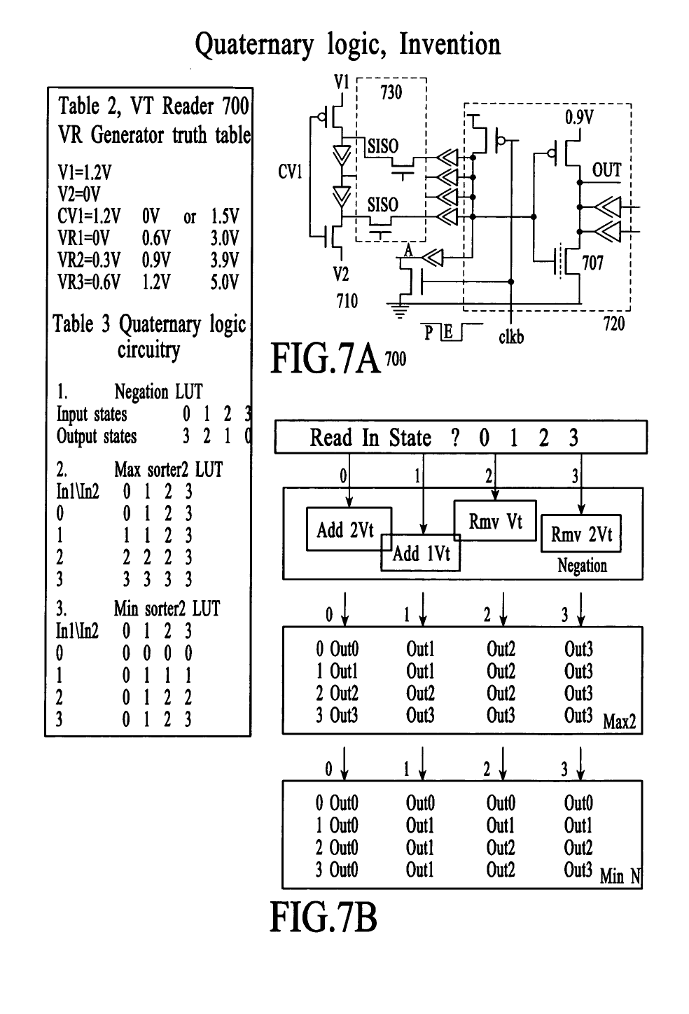

FIGS. 6B and 6C shows the reconfiguration of a digital signal comparator from a MUX and SCL NAND gate. This circuit may act as analog to digital translator to measure the stored charge level or decode the dual bits. FIG. 7 shows voltage reference taps which can be connected to the MLC type SCL NAND gate. Selected level match action reads the stored states with binary output. The selection code then becomes the digital translation of stored charges. It can also link to a binary D-type Flip Flop. Still another option is to read the variable resistance of the 707 device. The I-V look up table should clearly distinct the Vt states. This technique was disclosed in disclosure 3092P by the author.

The reverse action is also realizable. According to the method depicted in FIGS. 5D-5F, the device 707 can be set to any charge level (Vt), by the charge pump apparatus means and stored software procedure routines. The combined two way conversions make this facility an ideal Digital-to-analog and analog-to-digital translation (DADT) apparatus.

The subsystem in FIG. 7A 700 can thus be characterized as the hardware engine of a quaternary switching circuit. Quaternary logic state machine is composed of a shared reference voltage bank port 710, selection MUX 730, and a MLC NAND 720, together with a shared charge pump, logic operators and LUT drivers.

Table 2 below shows the simple VR generator truth table. The reference taps are derived from rail to rail voltages with SBD diode drops or offsets (0.3V per step) either from VCC or above GND.

TABLE 2
Vt Reader 700VR Generator truth table

| | |
|---|---|
| V1 = 1.2V | |
| V2 = 0V | |
| CV1 = 1.2V | 0V |
| VR1 = 0V | 0.6V |
| VR2 = 0.3V | 0.9V |
| VR3 = 0.6V | 1.2V |

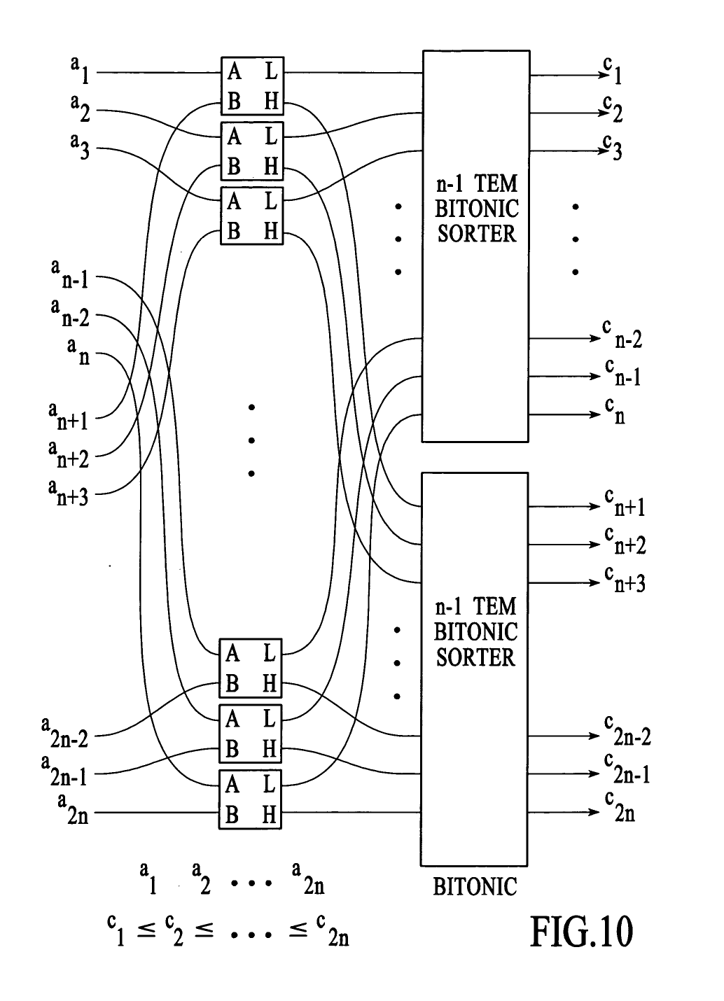

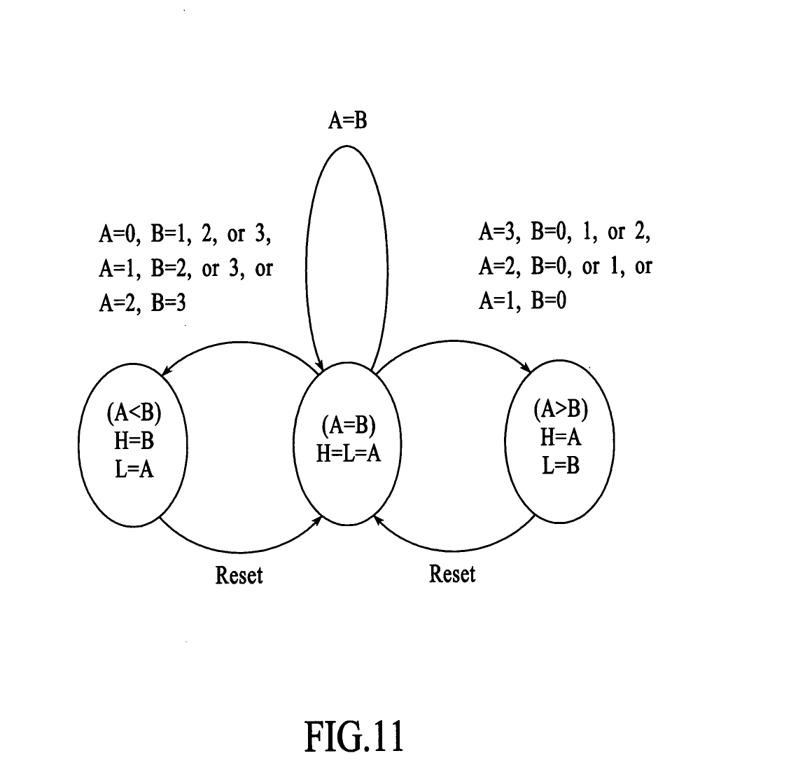

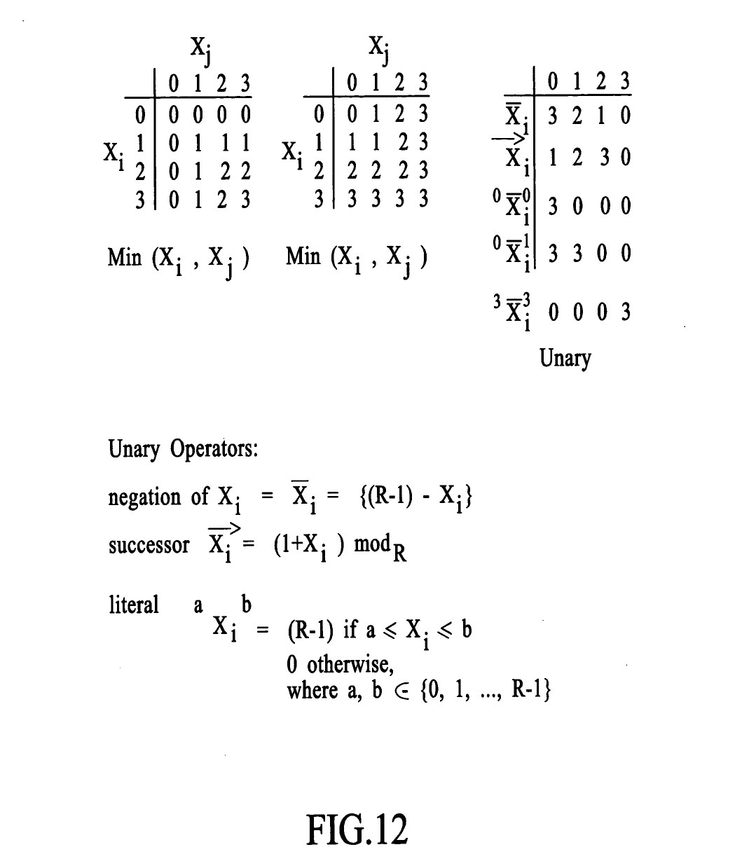

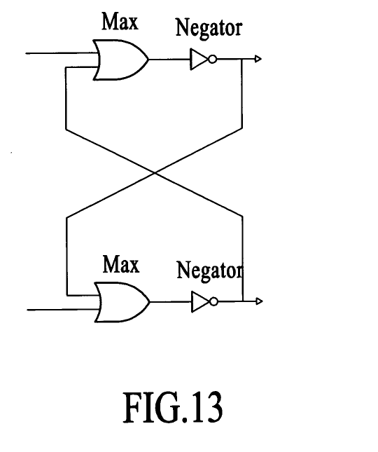

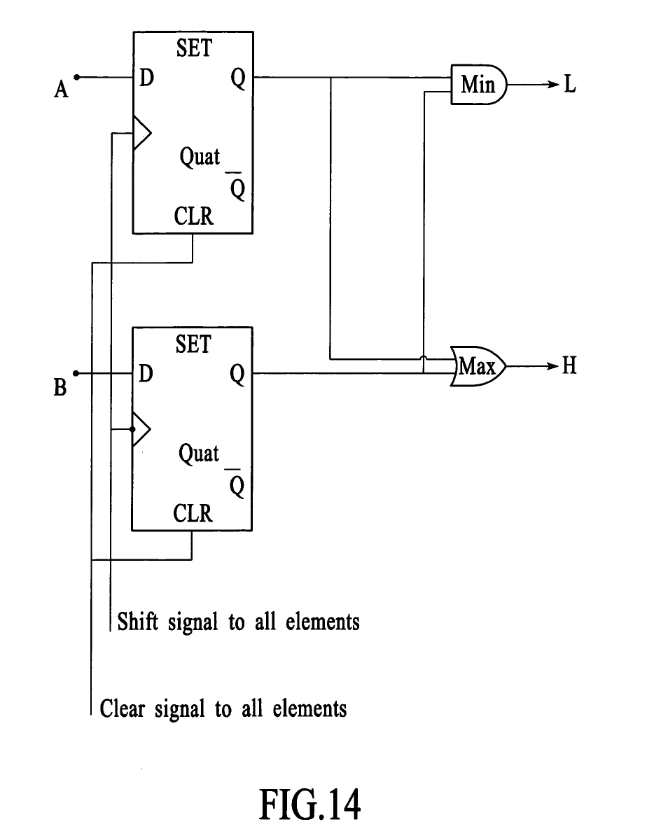

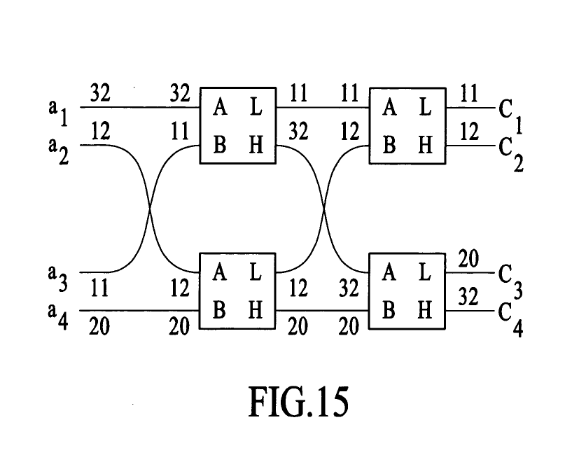

Quaternary Logic Circuitry and Exemplary Implementation of Selected Logic Operations Tables 3-1˜3 are the initial implementations of 3 quaternary logic operators. Assumptions are that each of the input variables has 4 states { 0,1,2,3 }. The flow diagrams in FIG. 7B show the lookup table entries between 2-way inputs and the output states from the corresponding operators—The negation, Min, and Max operator. Therefore, the operation can be realized with the Psuedo Quaternary hardware engine comprised of VR taps, charge pump facility, MUX, a MLC NAND gate as analog comparator, and stored truth table of operators. FIG. 10 is a 2 n-digit quaternary number sorter. FIG. 11 is the state transition diagram of the comparator, FIG. 12 is the truth table of the quaternary logic. FIG. 13 is a quaternary latch. FIG. 14 is the design of the quaternary comparison unit. FIG. 15 illustrates the sorting operation for 4 quaternary numbers using the quaternary latch, unary, max, and min operators.

TABLE 3-1
Negation LUT of 2-way quaternary Negation operation

| | |
|---|---|
| Input | 0 1 2 3 |
| Output | 3 2 1 0 |

TABLE 3-2
Max sorter2 LUT of 2-way quaternary MAX operation

| | |
|---|---|
| In1\In2 | 0 1 2 3 |
| 0 | 0 1 2 3 |
| 1 | 1 1 2 3 |
| 2 | 2 2 2 3 |
| 3 | 3 3 3 3 |

TABLE 3-3
Min sorter2 LUT of 2-way quaternary Min operation

| | | |
|---|---|---|
| In1\In2 | | 0 1 2 3 |
| 0 | | 0 0 0 0 |
| 1 | . . . | 0 1 1 1 |
| 2 | | 0 1 2 2 |
| 3 | | 0 1 2 3 |

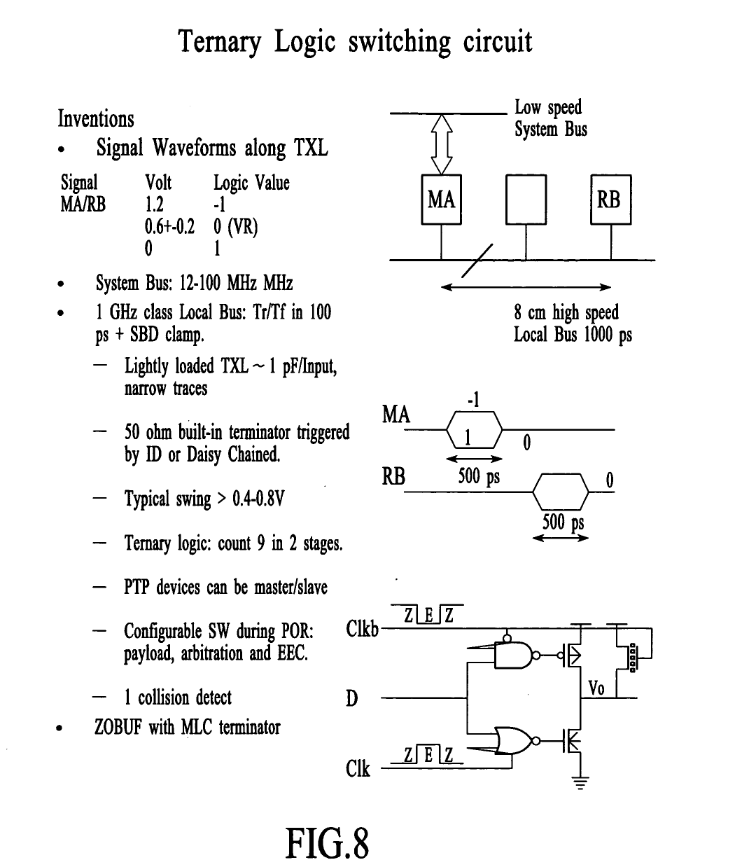

FIG. 8 depicts a simple tri-state circuit using SCL type gates and MLC switch where level 1 trinary switching is realized. The circuit comprises one 2-way NAND and 1 2-way NOR and 1 MLC biasing transistor. During the active timing window, the unit drives either 1(Low state, 0V) or −1(High state, 1.2V) to the PCB line. During the idle or standby state, it consumes no power, the CMOS totem pole is off, and the MLC switch couples to VR (0.6V), The MLC size ( or a pass transistor driven by MLC switch) determines the value of termination resistor. One of the obvious benefits is that it provides off-chip transmission net termination saving board space. Besides the low power nature, the main advantage is the PCB net, with a modified protocol for addressing and commands, now carrying 3 level signals. A 50% BW increments!

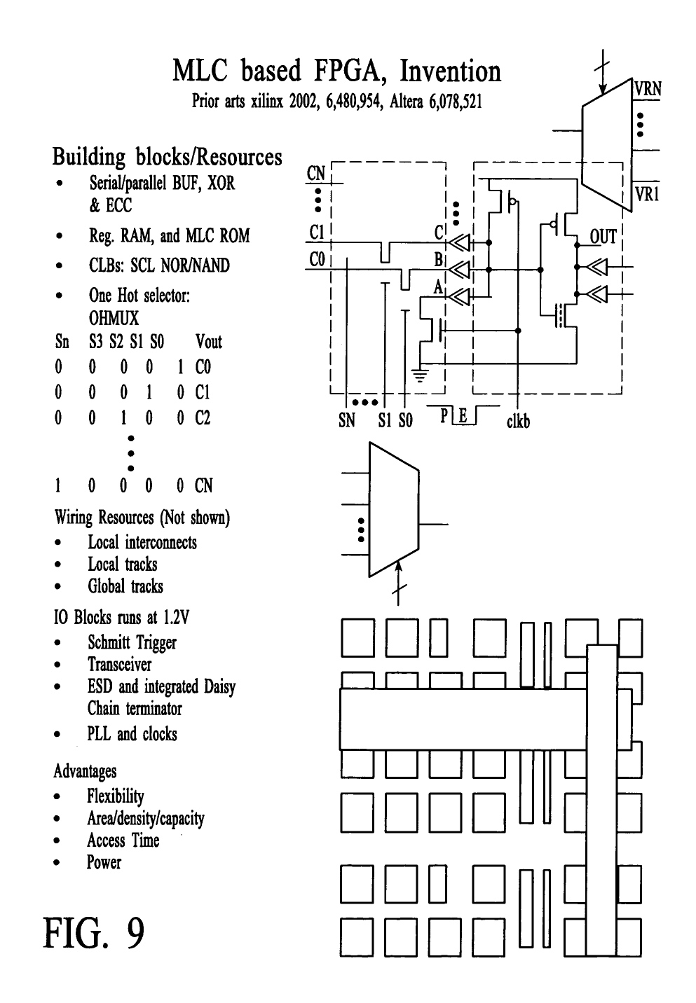

FIG. 9 illustrates the concept of an intelligent memory chip embodiments encompassing large MLC memory arrays. It also builds in with densest logic arrays, and supports analog, binary, ternary and quaternary logic operations. The device excels in space management, improved functional capacity, and can be deployed with great RAS flexibility and consumes least power.

A Multiple-Valued Logic Sorter Using Multiple-Level Storage Cell (Flash) and Variable Threshold Transistors

The present mainstream computers are based on two-valued (binary) logic. Boolean algebra and its associated developments have helped the acceptance and exploitation of binary logic. The most pressing problems in binary systems, however, are too many interconnection or bandwidth is low on a per signal wire basis, both for on chip and between chips. Multiple-valued logic (MVL) on the other hand can raise information contents per interconnection. Comparing the number of interconnection lines with required 100 binary lines, quaternary logic only needs 50 lines. Furthermore, in general for any numeric system, the larger the radix the smaller the number of digits is needed to express a given quantity. For a cost or complexity criterion where system hardware is proportional to the digit capacity R·d, where R is the radix and d is the necessary number of digits, quaternary logic scores the same as binary logic.

For another cost or complexity criterion where system hardware is independent of R, the total system cost of quaternary logic scores only half of that of binary logic system. While potential applications call for a true multi-state device higher than binary, here in this invention, we proposed a psuedo multilevel logic hardware and software solution. It is practical to integrate binary system with quaternary logic system. The coexistence of multilevel logic and binary constructs allows the trinary logic driver and quaternary sorter in accordance with the present invention to be integrated with other parts of the system. While ternary logic has the advantage of a balanced system values for arithmetic {−1,0,1}, quaternary is convenient for binary interfacing between R=2 and R=4. The sorter in accordance with the present invention uses quaternary logic.

Using the present invention of the MLSC and VTL to implement the sorter in accordance with the present invention, the advantage of the SFPGA efficiency is utilized. In general, FPGA wins in programmability, re-configurability, integration and development cycle but loses in some throughput performance, area utilization and power consumption against ASIC. Nevertheless, the SFPGA mitigate these shortcomings but scores high in density, low power, high speed and easy to reconfigure.

Quaternary Logic Blocks

Referring now to FIG. 10, the sorter in accordance with the present invention uses the well-known sorting-by-merging scheme to construct the sorting network or sorting memory. The data represented in quaternary form are combined two at a time to form ordered list of length two; these lists are merged two at a time to form ordered lists of length four, etc., until all data are merged into one ordered list. In FIG. 10, a bitonic sorter of 2n inputs and 2n outputs is constructed by interconnecting two bitonic sorters, each of n inputs and n outputs. Note that n is power of 2.

To sort 2^{p} data using bitonic sorters requires only (½)p(p+1) stages each with 2^{p-1} comparison units for (p²+p)2^{p-2} units, where bitonic referring to a sequence of data formed by juxtaposition of two monotonic sequences, one ascending, the other descending. It is more cost-effective than a normal crossbar in hardware requirement.

To illustrate the construction rule and the sorting operation described above, refer to FIG. 15 now. In FIG. 15, p=2 and it is a bitonic sorter of 4 inputs and 4 outputs. It is constructed by one stage of comparison units interconnected with two bitonic sorters of half size, each being a bitonic sorter of 2 inputs and 2 outputs. This follows the construction rule of FIG. 10. As illustrated, the sorter takes bitonic inputs 32, 12, 11, 20 and producing outputs 11, 12, 20, 32 as an ordered list. This example uses inputs of length 2, however inputs of arbitrary length work under the same principle.

To complete the implementation of the sorter's functionality, the comparison unit or comparator with inputs A and B and outputs H and L should have a specification as depicted in FIG. 11. The data are transmitted serially most significant quaternary digit first in and out of the unit. A reset signal places the unit in the A=B state and as long as the A and B digits agree it remains in this state with its outputs equal to its inputs. When the A and B digits disagree the unit goes to the A<B or the A>B state and remains there, skipping further incoming digits for comparison and shifting them out directly to the next stage of units.

To realize the comparator, available quaternary logic is chosen and operational algebra is used. FIG. 12 gives the definition in truth table as well as mathematical form the Min, Max and other useful operators. One of ordinary skill in the art readily recognizes that these operators are by no means exhaustively complete. However, a latch that is essential in sequential circuit design can be realized as shown in FIG. 13 by using some of these operators. In comparison to latch {0,1} in the binary logic, the quaternary latch can store {0,1,2,3} one of the four values. The theory in quaternary logic is much more limited comparing to that of binary logic where Boolean algebra and associated development can be used.

A design of the quaternary comparison unit in accordance with the present invention is given in FIG. 14. All units of the sorter are reset by the clear signal initially. With all data coming into the units, the shift signal applies for one quaternary digit at a time, on the fly data flow from left to right serially resulting in sorted data at the output of the sorter.

The sorter in accordance with the present invention uses the well-known sorting-by-merging scheme to construct the sorting network or sorting memory. The data represented in quaternary form are combined two at a time to form ordered list of length two.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A logic circuit comprising:
a logic switching circuit which includes a multilevel storage cell (MLSC) and variable threshold logic gates (VTL) among other on-chip apparatus to yield an improved space, power, and time-efficient performance device.

2. The logic circuit of claim 1 wherein the logic switching circuit comprises a quaternary logic switching circuit.

3. The logic circuit of claim 1 wherein the logic switching circuit comprises a trinary logic switching circuit.

4. The logic circuit of claim 1 which provides semiconductor process procedures, flow controls known as CMOS transistors, MLC Flash transistors, and Schottky barrier diodes.

5. The logic circuit of claim 1 which includes but is not limited to all conventional CMOS and SCMOS logic and memory circuit topology or configuration, large circuitry units, interface and coupling techniques at chip, and PCB levels.

6. The logic circuit of claim 1 which further includes generating and processing analog signals, transformation, conversion, compressing, expanding, encoding, decoding, arithmetic operations.

7. The logic circuit of claim 1 which includes on-chip apparatus to adjust device parameters of certain circuit element, reconfiguring small and large circuit connections, wiring adjustment to portions of interfaces.

8. The logic circuit of claim 1 which further includes software driven macros of hardwired constructs, soft macros, procedures of protocols, algorithms, state machines, OS routines, place and routing tables, logic look up tables.

9. The logic circuit of claim 1 which includes real time signal sampling, coupling, manipulating, processing, forward and reverse transformation, arithmetic and algebraic calculations.

10. The logic circuit of claim 2 including serial comparison units made of quaternary combinational and sequential circuits.

11. The logic circuit of claim 10 which is constructed using bitonic construction rules.

12. The logic circuit of claim 10 wherein the combinational circuits consist of Min, Max and unary quaternary logic operators.

13. The logic circuit of claim 10 wherein the sequential circuits comprise latches implemented using quaternary logic operators.

14. The logic circuit of claim 10 wherein the operation of the sorter works sequentially on quaternary inputs.

15. The logic circuit of claim 10 in which the comparison units are interconnected.

16. The logic circuit of claim 15 in which the comparison units are designed by using quaternary Min, Max and sequential latches.

17. The logic circuit of claim 15 wherein the interconnection rules use sorting by merging scheme where the sorter of size 2n is constructed by connecting a stage of comparison units with two sorters of size n.

18. The logic circuit of claim 10 wherein the sorter operation operates on large number of quaternary inputs of any arbitrary length.

19. The logic circuit of claim 10 wherein as quaternary data flows through the logic circuit, all stages of comparison units work on their respective inputs in the same fashion by its comparison units.

20. The logic circuit of claim 18 wherein the respective inputs are fed by entering most significant digit first and controlled by shifting one digits at a time through the logic circuit.

21. The logic circuit of claim 1 wherein the logic circuit comprises a sorter.

22. The logic circuit of claim 1 wherein the logic circuit utilizes SCL based DADT technologies.

23. The logic circuit of claim 1 wherein the logic circuit is utilized in universal integrated circuits.

24. The logic circuit of claim 1 wherein the logic circuit voltage is utilized in a multilevel cell (MLC).

25. The logic circuit of claim 1 wherein the operations follow a given truth table.

26. The logic circuit of claim 1 wherein a diode capacitor ladder chain is utilized on an on-chip power supply multiplier to support internal high voltage operations.

27. The logic circuit of claim 3 wherein a trinary signal wire provides a bandwidth increase when utilized in a printed circuit board (PCB) net driver.
